(19) United States
(12) Patent Application Publication
(10) Pub. No.: US 2026/0089928 A1
(43) Pub. Date: Mar. 26, 2026

(54) METHOD FOR FORMING CONDUCTORS AND THEIR CONTACTS WHICH CARRY SIGNALS FOR ADVANCED SEMICONDUCTOR MEMORY DEVICES WITH SELF-ALIGNED STI SUPPORT BEAMS

(71) Applicant: Nanya Technology Corporation, New Taipei City (TW)

(72) Inventor: Da-Zen CHUANG, Taipei City (TW)

(73) Assignee: Nanya Technology Corporation, New Taipei City (TW)

(21) Appl. No.: 18/893,375

(22) Filed: Sep. 23, 2024

(51) Int. Cl. H10B 12/00

(52) U.S. Cl. CPC H10B 12/482; H10B 12/02

(57) ABSTRACT

This invention provides a method for forming conductors and their contacts which carry signals for advanced semiconductor memory devices with self-aligned STI support beams, during the method process a patterning layer including a sub shallow trench isolation pattern in a first direction and a sub support beam pattern in a second direction perpendicular to the first direction is provided over a substrate, a STI etching is performed in a way that an anisotropic STI etching is executed in the second direction and a STI tilt etching is executed in the first direction simultaneously, whereby shallow trenches in the second direction with the support beams inside them hanging underneath the sub support beam pattern and adjoining the substrate underneath the sub shallow trench isolation pattern are provided. The support beams mechanically support the shallow trenches during the whole STI manufacturing to suppress the bending, deforming, or tilting of STI.

### BACKGROUND OF THE INVENTION

### Field of the Invention

The present invention relates to the field of semiconductor processing, and more particularly to a method for forming a semiconductor structure to carry signals for advanced semiconductor memory devices with self-aligned STI support beams.

### Description of the Prior Art

For advanced semiconductor memory IC, such as DRAM, further pushing of geometry has made manufacture of such IC getting extremely difficult. Take DRAM for instance, bit lines are narrow and tall, which makes bit line patterning (both photolithography and etching) hard to immune from pattern wobbling, tilting, and necking. In addition, size of bit-line contacts is too small so that not only patterning of the bit-line contacts is troublesome, but also the integration of the bit line contacts and bit lines is very complicate in order to avoid the electrical short between the bit line contacts and cell contacts, and among bit lines from happening.

There is still another problem, sizes of patterned active area (AA) islands are so tiny that they tend to bend or shift from their ideal positions on a semiconductor substrate during the formation of shallow trench isolation (STI). This makes following steps, especially alignment of photolithography, difficult. In addition, the active area islands may get too close to each other and cause electrical short. All these issues result in lower yield.

Same thing may happen on a strip-type STI, which separates the manufacture of STI into two steps, one step to form the STI at the X axis direction and another step to form the STI at the Y axis direction. There is also a possibility of deforming or bending of a hard mask strip after etching shallow trenches in a semiconductor substrate. This also makes following steps, especially alignment of photolithography, difficult and therefore results in lower yield.

To solve the above problems, the present invention provides a method for forming conductors and their contacts which carry signals for advanced semiconductor memory device with self-aligned STI support beams.

### SUMMARY OF THE INVENTION

One purpose of the present invention is to provide a robust STI structure and a self-aligned buried bit line inside the STI structure during processes for manufacturing memory devices such as DRAM to let the manufacture of advanced memory IC ease and have good yield as semiconductor geometry shrinks further.

In one embodiment, the present invention provides a method for forming conductors and their contacts which carry signals for advanced semiconductor memory device with self-aligned STI support beams. In this embodiment, a first dielectric layer is formed on a silicon substrate and a first patterning layer is formed on the first dielectric layer, wherein the first patterning layer comprises a sub shallow trench isolation pattern in a first direction and a sub support beam pattern in a second direction perpendicular to the first direction. Next, etching the first dielectric layer unprotected by the first patterning layer to exposed the silicon substrate and then removing the first patterning layer such that a patterning first dielectric layer are provided, wherein the patterning first dielectric layer comprises the sub shallow trench isolation pattern and the sub support beam pattern. Then, performing a first STI etching in a way that an anisotropic STI silicon etching is executed in the second direction and a STI tilt silicon etching is executed in the first direction simultaneously, whereby a plurality of first shallow trench in the second direction is provided and part of the silicon substrate underneath the sub support beam pattern is removed to leave a plurality of silicon support beams hanging underneath the sub support beam pattern inside the first shallow trenches and adjoining the silicon substrate underneath the sub shallow trench isolation pattern. Subsequently, a first thermal oxidation process is executed such that a first silicon dioxide liner layer is formed along each of the first shallow trenches and the silicon support beams are self-transformed to silicon dioxide support beams in the first shallow trenches. Then, forming a layer of first conductor on the patterning first dielectric layer and performing a first chemical mechanical polish process to stop on the patterning first dielectric layer to have the first conductor filling the first shallow trenches. Removing part of the first conductor filled in the first shallow trenches to form a plurality of first signal-carrying conductor and first conductor pillars integrated with the plurality of first signal-carrying conductor, wherein the first conductor pillars are underneath the silicon dioxide support beams and to be electrically connect contacts of the plurality of first signal-carrying conductor. A first silicon dioxide deposition process is performed to have the first signal-carrying conductor and first conductor pillars buried in the first shallow trenches filled with silicon dioxide, performing a second chemical mechanical polish process to form a first shallow trench isolation structure. Then, a second STI etching process is performed in the second direction to the sub shallow trench isolation pattern of the patterning first dielectric layer to form an active area island pattern divided by a plurality of second shallow trench. A second silicon dioxide deposition process is executed to fill the plurality of second shallow trench and then performing a third chemical mechanical polish process to form a second shallow trench isolation structure. Subsequently, a first photolithography and etching process is performed to expose first conductor pillars and portion of the silicon substrate at the active area island pattern to define locations of the contacts of the plurality of first signal-carrying conductor. Then, depositing a layer of second conductor and performing a fourth chemical mechanical polish process to form the contacts of the plurality of first signal-carrying conductor.

In an implementation, the sub shallow trench isolation pattern and the sub support beam pattern of the first patterning layer interlace and adjoin to each other.

In another embodiment, prior to the formation of the contacts of the first signal-carrying conductor, a plurality of buried second signal-carrying conductor is done, in which after the formation of the second shallow trench isolation structure which divides the area island pattern, a third STI etching process is performed in the second direction to form a plurality of third shallow trench passing through the active area island pattern. A second thermal oxidation process is executed to form a second silicon dioxide liner layer around the plurality of third shallow trench. Then, a plurality of second signal-carrying conductor inside the plurality of third shallow trench is formed. A third silicon dioxide deposition process is executed to fill the plurality of third shallow trench and bury the plurality of second signal-carrying conductor. A chemical mechanical polish process is perform to form a third shallow trench isolation structure with buried second signal-carrying conductors inside them.

Further, in one aspect, the present invention provides a semiconductor structure with self-aligned buried conductors inside a STI structure and their contacts which carry signals for advanced memory devices, which comprises a substrate having a first shallow trench isolation structure in a first dimension, wherein the first shallow trench isolation structure includes a plurality of first trench filled with silicon dioxide along the first dimension; a plurality of conductor each of which buried in one of the first trenches filled with silicon dioxide and being self-aligned with the first trench along the first dimension; a plurality of conductor pillars extended along a second dimension perpendicular to the first dimension being integrated with the conductors; and a plurality of contacts each of which provided on one of the conductor pillars.

The semiconductor structure may further comprise a second shallow trench isolation structure having a plurality of second trench filled with silicon dioxide along the second dimension and a plurality of active area region each of which being positioned between a pair of the second trenches filled with silicon dioxide, and each of the contacts occupies a portion of one of the active area regions.

The semiconductor structure may further comprise a plurality of second conductors buried in a third shallow trench isolation structure having a plurality of third trench filled with silicon dioxide along a third dimension and passing through the active area regions. The third dimension is perpendicular to the first dimension and the second dimension. The second conductors may be positioned underneath the contacts.

### BRIEF DESCRIPTION OF THE DRAWINGS

Other objects and advantages of the invention will become apparent upon reading the following detailed description and upon reference to the accompanying drawings in which:

FIG. 1A through FIG. 11A are respective schematic top views of a semiconductor structure at various stages of a method for forming conductors and their contacts which carry signals for advanced semiconductor memory device with self-aligned STI support beams according to a first embodiment of the present invention;

FIG. 1B through FIG. 11B are schematic cross sectional views along a Y cutting line of FIG. 1A through FIG. 11A, respectively;

FIG. 1C through FIG. 11C are schematic cross sectional views along an X cutting line of FIG. 1A through FIG. 11A, respectively;

FIG. 12A is a schematic top view of a semiconductor structure manufactured by a method for forming conductors and their contacts which carry signals for advanced semiconductor memory device with self-aligned STI support beams according to a second embodiment of the present invention; and

FIG. 12B is schematic cross sectional view along an X cutting line of FIG. 12A.

### DETAILED DESCRIPTION OF THE PREFERRED EMBODIMENTS

The present invention will now be described by way of preferred embodiments with references to the accompanying drawings. Like numerals refer to corresponding parts of various drawings. Please note well-known circuits, structures and techniques may not be shown in detail in order not to obscure the aspects of the disclosure. Various embodiments will be disclosed herein. However, it is to be understood that the disclosed embodiments are only used as an illustration that can be embodied in various forms. In addition, each of the examples given in connection with the various embodiments are intended to be illustrative but not limiting to. Further, the figures are not necessarily conform to the sizes and dimension ratios of actual structures, and some features are magnified to show details of particular components (and any dimensions, materials, and similar details shown in the figures are intended to be illustrative and not limiting to). Therefore, the particular structural and functional details are disclosed herein are not interpreted as limitations, but are used only to teach those skilled in the relevant field technicians to practice the basis of the disclosed embodiments.

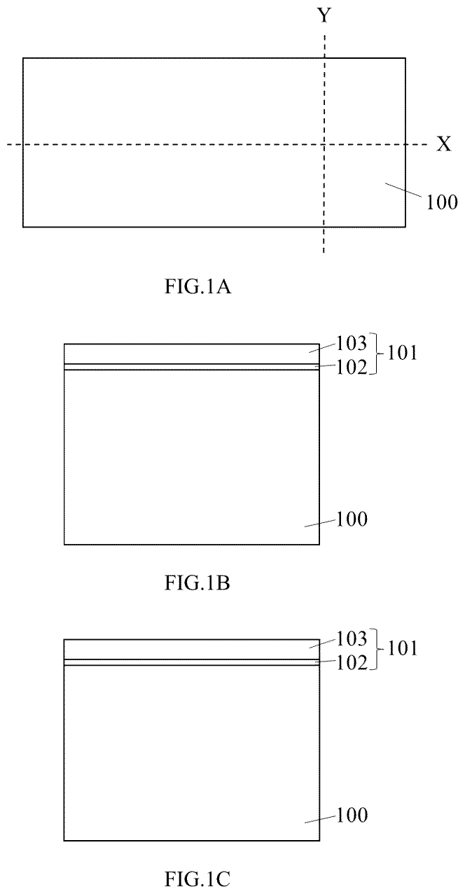

Turning now to the drawings, FIG. 1A, FIG. 1B and FIG. 1C show the semiconductor structure respectively from the schematic top view, the schematic cross sectional view along the Y cutting line of FIG. 1A and the schematic cross sectional view along the X cutting line of FIG. 1A at a first stage of the method for forming conductors and their contacts which carry signals for advanced semiconductor memory devices with self-aligned STI support beams according to the first embodiment of the present invention.

At the first stage, a silicon substrate 100 is provided and a first dielectric layer 101 is formed on the silicon substrate 100. The first dielectric layer 101 may comprise a silicon dioxide layer 102 grown on the silicon substrate 100 and a silicon nitride layer 103 deposited on the silicon dioxide layer 102.

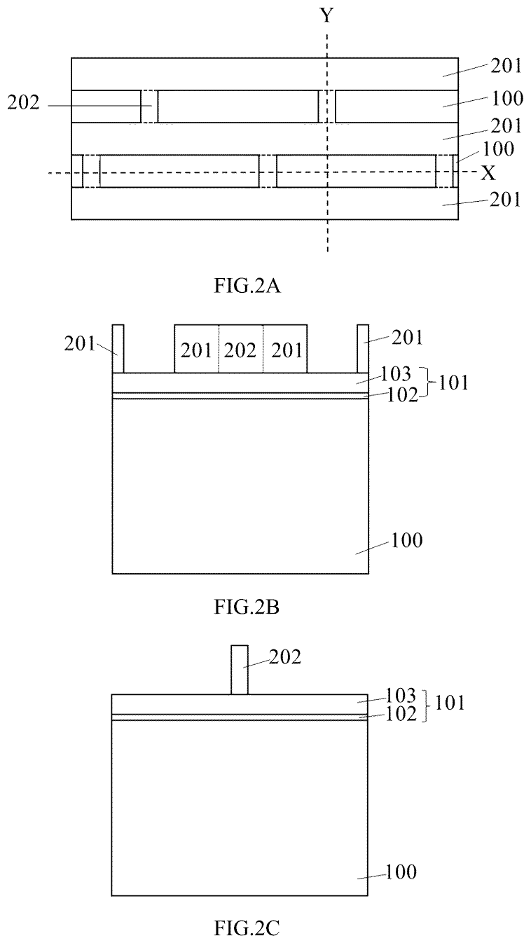

FIG. 2A, FIG. 2B and FIG. 2C show the semiconductor structure respectively from the schematic top view, the schematic cross sectional view along the Y cutting line of FIG. 2A and the schematic cross sectional view along the X cutting line of FIG. 2A at a second stage of the method according to the first embodiment.

At the second stage, a first patterning layer is provided on the first dielectric layer 101. The first patterning layer comprises a sub shallow trench isolation pattern 201 in the X direction and a sub support beam pattern 202 in the Y direction. The sub shallow trench isolation pattern 201 and the sub support beam pattern 202 may be integrated in the first patterning layer in which the sub shallow trench isolation pattern 201 and the sub support beam pattern 202 interlace and adjoin to each other.

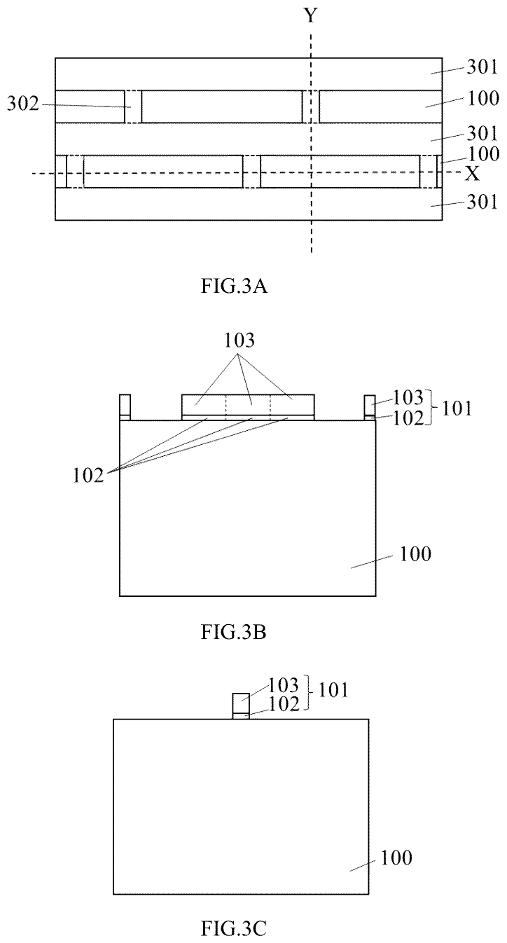

FIG. 3A, FIG. 3B and FIG. 3C show the semiconductor structure respectively from the schematic top view, the schematic cross sectional view along the Y cutting line of FIG. 3A and the schematic cross sectional view along the X cutting line of FIG. 3A at a third stage of the method according to the first embodiment.

At the third stage, etching the first dielectric layer 101 unprotected by the first patterning layer to exposed the silicon substrate 100. Then, the first patterning layer is removed to leave the first dielectric layer 101 patterned on the silicon substrate 100. The first dielectric layer 101 patterned on the silicon substrate 100 comprises a sub shallow trench isolation pattern 301 and a sub support beam pattern 302, respectively mapping with the sub shallow trench isolation pattern 201 and the sub support beam pattern 202.

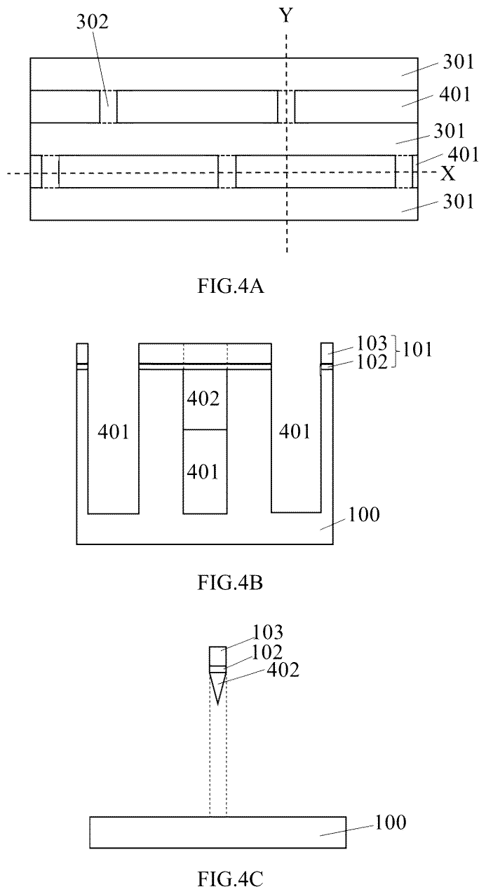

FIG. 4A, FIG. 4B and FIG. 4C show the semiconductor structure respectively from the schematic top view, the schematic cross sectional view along the Y cutting line of FIG. 4A and the schematic cross sectional view along the X cutting line of FIG. 4A at a fourth stage of the method according to the first embodiment.

At the fourth stage, a first STI etching is performed in a way that an anisotropic STI silicon etching is executed in the Y direction and a STI tilt silicon etching is executed in the X direction simultaneously so that a plurality of first shallow trench 401 is provided in the silicon substrate 100 along the X direction and part of the silicon substrate 100 underneath the sub support beam pattern 302 is removed to leave a plurality of silicon support beams 402 hanging underneath the sub support beam pattern 302 inside the first shallow trenches 401 and adjoining the silicon substrate 100 underneath the sub shallow trench isolation pattern 301. The STI tilt silicon etching is not being anisotropic, and an etching recipe of the STI tilt silicon etching is tuned to be able to do lateral silicon etch slightly so that large portion of the silicon substrate 100 below the sub support beam pattern 302 may be removed in order to leave only small portion of the silicon substrate 100 (i.e. leftover silicon) right underneath the sub support beam pattern 302 to serve as the silicon support beams 402, as shown in FIG. 4C. The silicon support beams 402 inside the first shallow trenches 401 adjoining the silicon substrate 100 underneath the sub shallow trench isolation pattern 301 will mechanically support the first shallow trenches 401 to suppress the bending, deforming, or tilting of them.

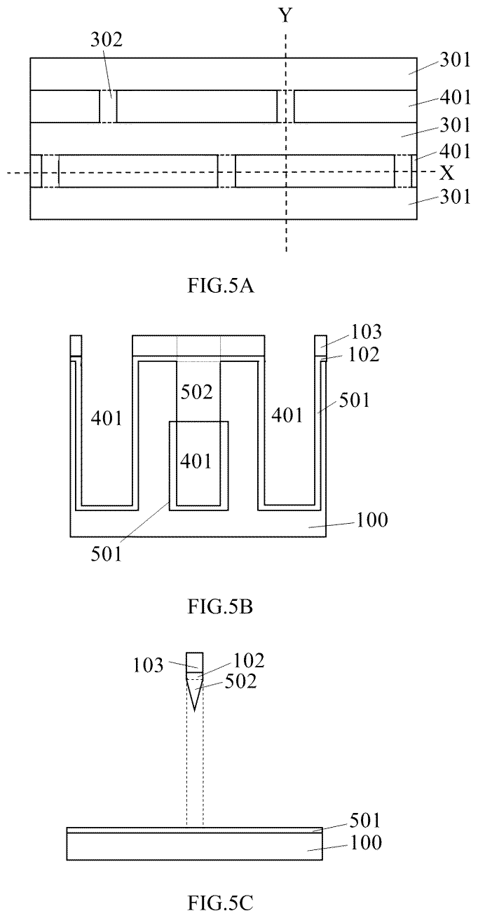

FIG. 5A, FIG. 5B and FIG. 5C show the semiconductor structure respectively from the schematic top view, the schematic cross sectional view along the Y cutting line of FIG. 5A and the schematic cross sectional view along the X cutting line of FIG. 5A at a fifth stage of the method according to the first embodiment.

At the fifth stage, a first thermal oxidation process is performed such that a first silicon dioxide liner layer 501 is formed around each of the first shallow trenches 401 and the silicon support beams 402 are self-transformed to silicon dioxide support beams 502 in the first shallow trenches 401.

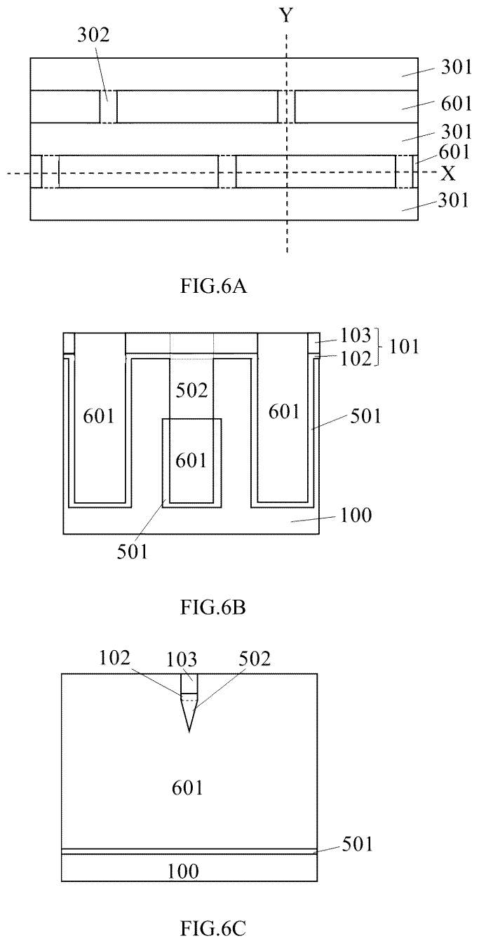

FIG. 6A, FIG. 6B and FIG. 6C show the semiconductor structure respectively from the schematic top view, the schematic cross sectional view along the Y cutting line of FIG. 6A and the schematic cross sectional view along the X cutting line of FIG. 6A at a sixth stage of the method according to the first embodiment.

At the sixth stage, a layer of first conductor like tungsten metal is deposited and then a first chemical mechanical polish process is performed to stop on the silicon nitride layer 103 of the patterned first dielectric layer 101 to have the first conductor 601 filling the first shallow trenches 401.

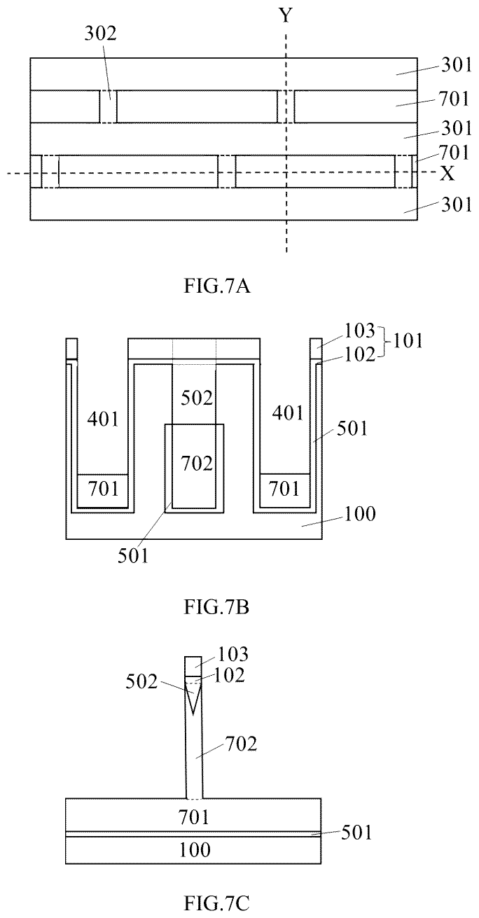

FIG. 7A, FIG. 7B and FIG. 7C show the semiconductor structure respectively from the schematic top view, the schematic cross sectional view along the Y cutting line of FIG. 7A and the schematic cross sectional view along the X cutting line of FIG. 7A at a seventh stage of the method according to the first embodiment.

At the seventh stage, a timely etch is performed to remove part of the first conductor 601 filled in the first shallow trenches 401 to form a plurality of first signal-carrying conductor 701 inside the first shallow trenches 401 and first conductor pillars 702 right underneath the silicon dioxide support beams 502 integrated with the plurality of first signal-carrying conductor 701. The first signal-carrying conductors 701 are formed at a bottom of the first shallow trenches 401 and horizontally self-aligned with the first shallow trenches 401, and the first conductor pillars 702 become vertical pillars. The locations of the silicon dioxide support beams 502 is the same as the first conductor pillars 702 so that the formation of the first conductor pillars 702 does not need additional photomask and photolithography steps to pattern. The first conductor pillars 702 in form of vertical pillars to be electrically connect contacts of the first signal-carrying conductors 701. The first signal-carrying conductor 701 may be served as a bit line of a memory cell. The first conductor pillar 702 may be a bit line pillar to electrically connect the contact of the bit line. The electrical connection of the bit line to the memory cell is via the bit line pillar, which can be formed in-situ with the formation of the bit line during the seventh stage.

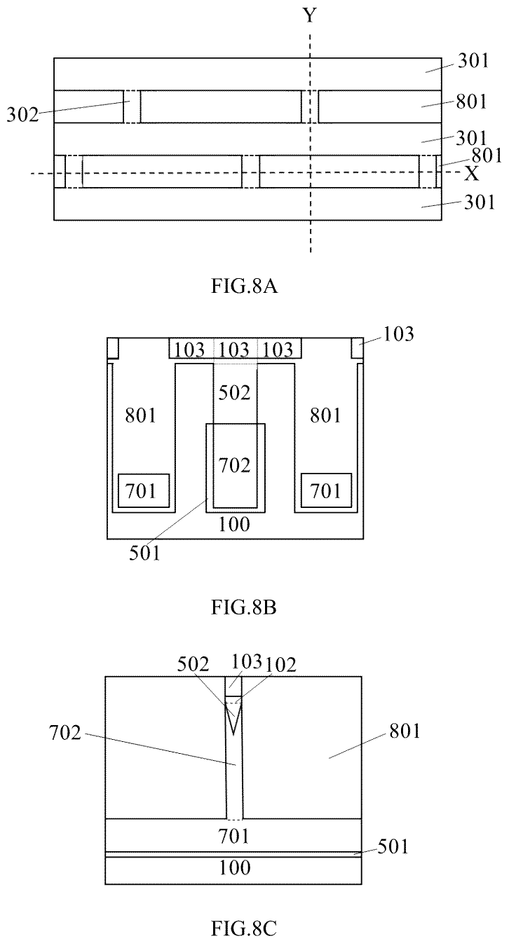

FIG. 8A, FIG. 8B and FIG. 8C show the semiconductor structure respectively from the schematic top view, the schematic cross sectional view along the Y cutting line of FIG. 8A and the schematic cross sectional view along the X cutting line of FIG. 8A at an eighth stage of the method according to the first embodiment.

At the eighth stage, a first silicon dioxide deposition process is performed to fill silicon dioxide in the first shallow trenches 401 and then a second chemical mechanical polish process is executed to complete the formation of a first shallow trench isolation structure 801 with the first signal-carrying conductors 701 buried in the first shallow trench isolation structure 801. In other words, self-aligned buried bit lines can be provided in a shallow trench isolation structure by this invention. And, there is no need of bit line photolithography and etching, the issues of bit line twisting, wobbling, tilting, necking, and electrical shorting to each other or electrical shorting to other patterns in DRAM cells can be resolved.

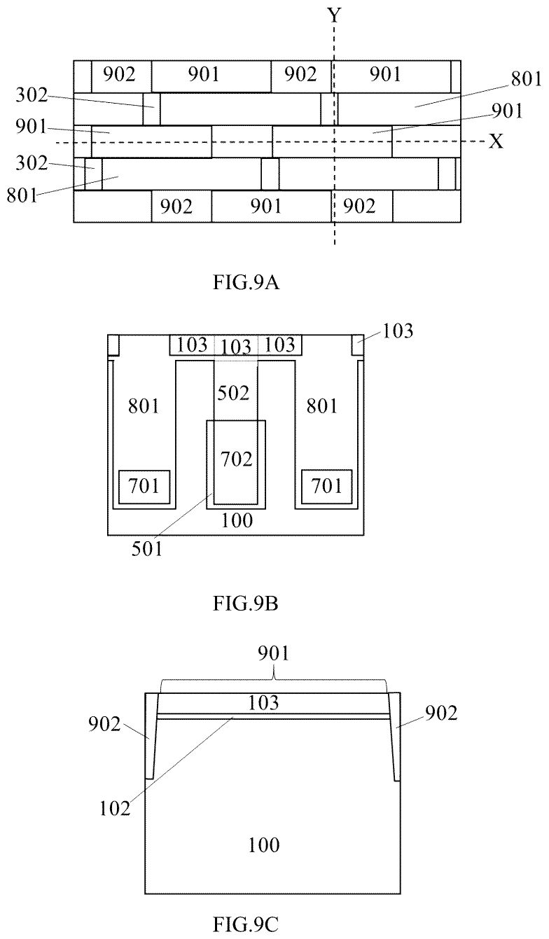

FIG. 9A, FIG. 9B and FIG. 9C show the semiconductor structure respectively from the schematic top view, the schematic cross sectional view along the Y cutting line of FIG. 9A and the schematic cross sectional view along the X cutting line of FIG. 9A at a ninth stage of the method according to the first embodiment.

At the ninth stage, a second STI etching process is performed in the Y direction to the sub shallow trench isolation pattern 301 of the patterned first dielectric layer 101 to form an active area island pattern 901 divided by a plurality of second shallow trench. A second silicon dioxide deposition process is performed to fill the plurality of second shallow trench and then performing a third chemical mechanical polish process to form a second shallow trench isolation structure 902. During the second STI etching process, the active area island pattern 901 is mechanically supported by the first shallow trench isolation structure 801 and the silicon dioxide support beams 501 so that the active area island pattern 901 may immune from bending or shifting from their ideal positions. This makes following steps, especially alignment of photolithography ease to improve the manufacturing yield.

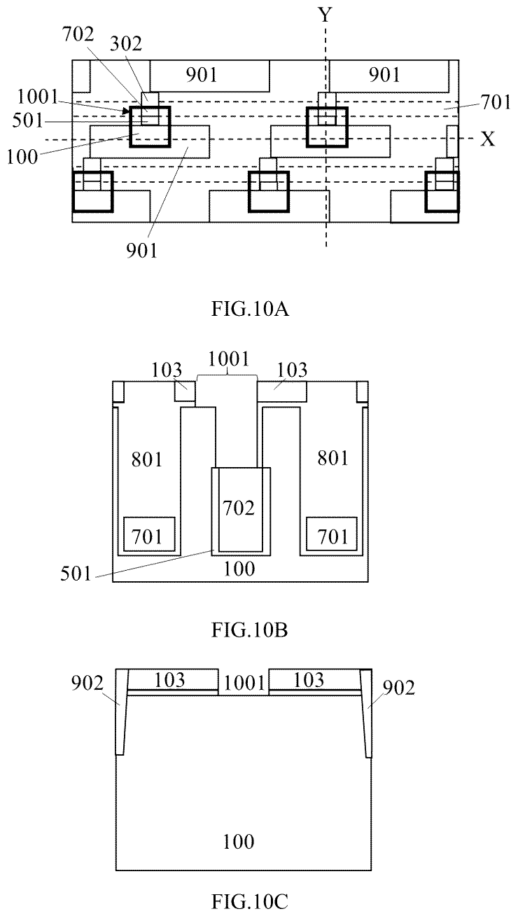

FIG. 10A, FIG. 10B and FIG. 10C show the semiconductor structure respectively from the schematic top view, the schematic cross sectional view along the Y cutting line of FIG. 10A and the schematic cross sectional view along the X cutting line of FIG. 10A at a tenth stage of the method according to the first embodiment.

At the tenth stage, a first photolithography and etching process is performed to expose the first conductor pillars 702 and portion of the silicon substrate 100 at the active area island pattern 901 to define locations 1001 of the contacts of the plurality of first signal-carrying conductor 701. At this stage, do bit line contact photolithography and etch to reveal both the top of bit line pillars and silicon surface of the active area island pattern 901 where the bit line is going to land. Then, the patterned photoresist layer for the formation of the bit line contact is removed.

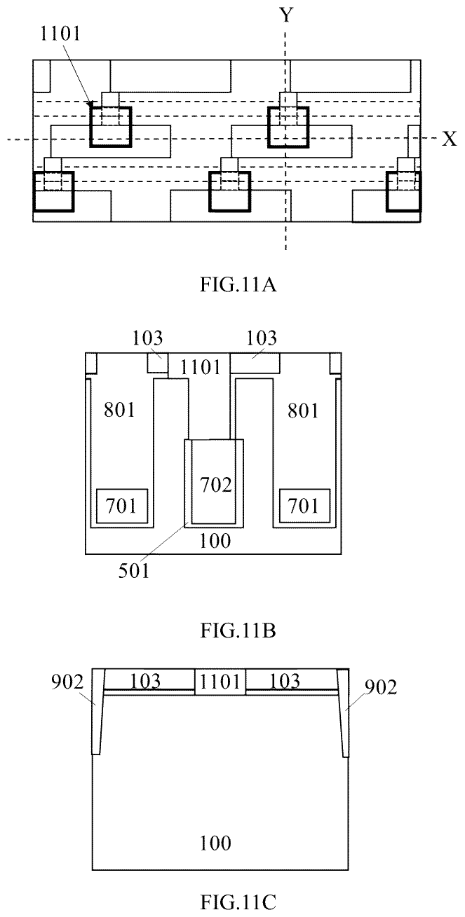

FIG. 11A, FIG. 11B and FIG. 11C show the semiconductor structure respectively from the schematic top view, the schematic cross sectional view along the Y cutting line of FIG. 11A and the schematic cross sectional view along the X cutting line of FIG. 11A at an eleventh stage of the method according to the first embodiment.

At the eleventh stage, depositing a layer of second conductor for example tungsten metal and performing a fourth chemical mechanical polish process to form the contacts 1101 of the plurality of first signal-carrying conductor 702.

In this invention, to complete electrical connection of the bit line via the bit line pillar to the DRAM cell for data steaming, the process steps at the tenth stage and eleventh stage are implemented to connect the bit line contact on the active area of the DRAM cell to the top of the bit line pillar, as shown in FIG. 11A.

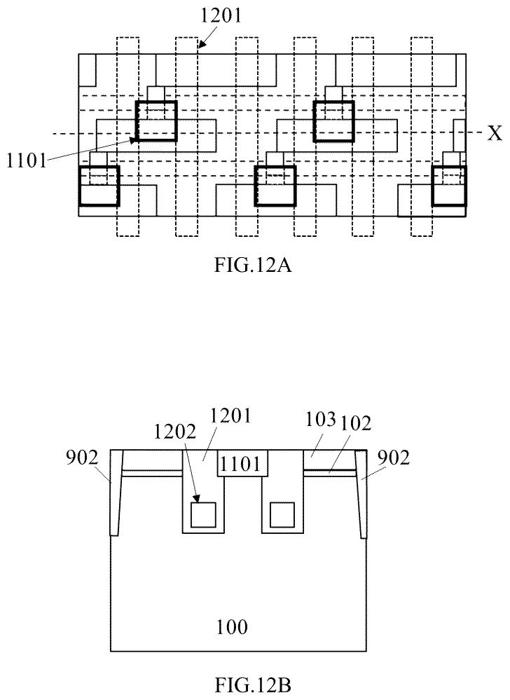

Please note above process flow and statement are for the ease of understanding the structure, process, and scope of this invention. In practical, the processing of word lines, for example buried word lines, to form DRAM cell transistor are completed before the making of the bit line contacts, as shown in FIG. 12A and FIG. 12B which are the semiconductor structure respectively from the schematic top view and the schematic cross sectional view along the X cutting line of FIG. 12A according to a method according to the second embodiment.

The process steps of the first stage through the ninth stage of the first embodiment are applicable to the second embodiment and then continued by process steps for the formation of the buried word lines 1202. See FIG. 12A and FIG. 12B, a third STI etching process in the Y direction is performed to form a plurality of third shallow trench passing through the active area island pattern 901. Then, a second thermal oxidation process is executed to form a second silicon dioxide liner layer around the plurality of third shallow trench. Next, forming a plurality of second signal-carrying conductor to be served as word lines inside the plurality of third shallow trench. A third silicon dioxide deposition process is executed to fill the plurality of third shallow trench and bury the plurality of second signal-carrying conductor. Then, a chemical mechanical polish process is performed to form a shallow trench isolation structure 1201 with the buried word lines 1202 inside them. Then, the making of the bit line contacts follow, namely, the process steps at the tenth stage to the eleventh stage of the first embodiment are applied to the subsequent steps of the second embodiment to complete the electrical connection of the bit line via the bit line pillar to the DRAM cell for data streaming. In this invention, the arrangement of the advanced semiconductor memory device (for example, DRAM), such as active area, word line (WL) and bit line (BL), is all square without any pattern going diagonal or in certain angles. This makes photolithography of patterns for advanced memory cells easier.

The above-mentioned embodiments of the present invention are exemplary and not intended to limit the scope of the present invention. Various variation or modifications made without departing from the spirit of the present invention and achieving equivalent effects shall fall within the scope of claims of the present invention.

What is claimed is:

1. A method for forming conductors and their contacts which carry signals for advanced semiconductor memory device with self-aligned STI support beams, comprising:
providing a silicon substrate;
forming a first dielectric layer on the silicon substrate;
forming a first patterning layer on the first dielectric layer, wherein the first patterning layer comprises a sub shallow trench isolation pattern in a first direction and a sub support beam pattern in a second direction perpendicular to the first direction;
etching the first dielectric layer unprotected by the first patterning layer to exposed the silicon substrate;
removing the first patterning layer such that a patterning first dielectric layer are provided, wherein the patterning first dielectric layer comprises the sub shallow trench isolation pattern and the sub support beam pattern;
performing a first STI etching in a way that an anisotropic STI silicon etching is executed in the second direction and a STI tilt silicon etching is executed in the first direction simultaneously, whereby a plurality of first shallow trench in the second direction is provided and part of the silicon substrate underneath the sub support beam pattern is removed to leave a plurality of silicon support beams hanging underneath the sub support beam pattern inside the first shallow trenches and adjoining the silicon substrate underneath the sub shallow trench isolation pattern;
performing a first thermal oxidation process such that a first silicon dioxide liner layer is formed along each of the first shallow trenches and the silicon support beams are self-transformed to silicon dioxide support beams in the first shallow trenches;
forming a layer of first conductor on the patterning first dielectric layer and performing a first chemical mechanical polish process to stop on the patterning first dielectric layer to have the first conductor filling the first shallow trenches;
removing part of the first conductor filled in the first shallow trenches to form a plurality of first signal-carrying conductor and first conductor pillars integrated with the plurality of first signal-carrying conductor, wherein the first conductor pillars are underneath the silicon dioxide support beams and to be electrically connect contacts of the plurality of first signal-carrying conductor;
performing a first silicon dioxide deposition process to have the first signal-carrying conductor and first conductor pillars buried in the first shallow trenches filled with silicon dioxide; and
performing a second chemical mechanical polish process to form a first shallow trench isolation structure.

2. The method of claim 1, further comprising performing a second STI etching process in the second direction to the sub shallow trench isolation pattern of the patterning first dielectric layer to form an active area island pattern divided by a plurality of second shallow trench.

3. The method of claim 2, further comprising performing a second silicon dioxide deposition process to fill the plurality of second shallow trench and then performing a third chemical mechanical polish process to form a second shallow trench isolation structure.

4. The method of claim 3, further comprising performing a first photolithography and etching process to expose first conductor pillars and portion of the silicon substrate at the active area island pattern to define locations of the contacts of the plurality of first signal-carrying conductor.

5. The method of claim 4, further comprising depositing a layer of second conductor and performing a fourth chemical mechanical polish process to form the contacts of the plurality of first signal-carrying conductor.

6. The method of claim 3, further comprising performing a third STI etching process in the second direction to form a plurality of third shallow trench passing through the active area island pattern.

7. The method of claim 6, further comprising performing a second thermal oxidation process to form a second silicon dioxide liner layer around the plurality of third shallow trench.

8. The method of claim 7, further comprising forming a plurality of second signal-carrying conductor inside the plurality of third shallow trench.

9. The method of claim 8, further comprising performing a third silicon dioxide deposition process to fill the plurality of third shallow trench and bury the plurality of second signal-carrying conductor.

10. The method of claim 1, wherein the step for forming a first dielectric layer on the silicon substrate comprises forming a silicon dioxide layer on the silicon substrate and then forming a silicon nitride layer on the silicon dioxide layer.

11. The method of claim 1, wherein the sub shallow trench isolation pattern and the sub support beam pattern interlace and adjoin to each other.

12. A semiconductor structure with self-aligned buried conductors inside a STI structure and their contacts which carry signals for advanced memory devices, comprising:
a substrate having a first shallow trench isolation structure in a first dimension, wherein the first shallow trench isolation structure includes a plurality of first trench filled with silicon dioxide along the first dimension;
a plurality of conductor each of which buried in one of the first trenches filled with silicon dioxide and being self-aligned with the first trench along the first dimension;
a plurality of conductor pillars extended along a second dimension perpendicular to the first dimension being integrated with the conductors; and
a plurality of contacts each of which provided on one of the conductor pillars.

13. The semiconductor structure of claim 12, further comprising a second shallow trench isolation structure having a plurality of second trench filled with silicon dioxide along the second dimension, and a plurality of active area region each of which being positioned between a pair of the second trenches filled with silicon dioxide, and each of the contacts occupying a portion of one of the active area regions.

14. The semiconductor structure of claim 13, further comprising a plurality of second conductors buried in a third shallow trench isolation structure having a plurality of third trench filled with silicon dioxide along a third dimension and passing through the active area regions, wherein the second conductors are positioned underneath the contacts, the third dimension is perpendicular to the first dimension and the second dimension.
